(19) United States
(12) Patent Application Publication
(10) Pub. No.: US 2024/0161835 A1
(43) Pub. Date: May 16, 2024

(54) SEMICONDUCTOR DEVICE

(71) Applicant: ROHM CO., LTD., Kyoto (JP)

(72) Inventor: Takeharu IMAI, Kyoto (JP)

(21) Appl. No.: 18/503,258

(22) Filed: Nov. 7, 2023

(30) Foreign Application Priority Data
Nov. 14, 2022 (JP) 2022-181641

(51) Int. Cl. G11C 16/30

(52) U.S. Cl. CPC G11C 16/30

(57) ABSTRACT

A semiconductor device includes a boosted voltage generation circuit configured to generate a boosted voltage, a voltage adjustment circuit configured to limit the boosted voltage to a predetermined clamp voltage or lower by using a constant voltage element having a first temperature dependence, and a bias voltage generation circuit configured to adjust the clamp voltage by using a bias voltage having a second temperature dependence that is opposite in polarity to the first temperature dependence.

### CROSS-REFERENCE TO RELATED APPLICATION

This application is based upon and claims the benefit of priority from Japanese Patent Application No. 2022-181641, filed on Nov. 14, 2022, the entire contents of which are incorporated herein by reference.

### TECHNICAL FIELD

The present disclosure relates to a semiconductor device.

### BACKGROUND

Some semiconductor devices have a function of adjusting a boosted voltage (for example, a write voltage of a memory cell) by using a constant voltage element such as a Zener diode.

### BRIEF DESCRIPTION OF DRAWINGS

The accompanying drawings, which are incorporated in and constitute a part of the specification, illustrate embodiments of the present disclosure.

FIG. 1 is a diagram showing a comparative example of a semiconductor device.

FIG. 2 is a diagram showing a temperature dependence of a boosted voltage in the comparative example.

FIG. 3 is a diagram showing a first embodiment of a semiconductor device.

FIG. 4 is a diagram showing a second embodiment of the semiconductor device.

FIG. 5 is a diagram showing a temperature dependence of a boosted voltage in the second embodiment.

FIG. 6 is a diagram showing a third embodiment of the semiconductor device.

FIG. 7 is a diagram showing a temperature dependence of a boosted voltage in the third embodiment.

FIG. 8 is a diagram showing a fourth embodiment of the semiconductor device.

FIG. 9 is a diagram showing a temperature dependence of a boosted voltage in the fourth embodiment.

FIG. 10 is a diagram showing a fifth embodiment of the semiconductor device.

FIG. 11 is a diagram showing effects of improving a rewrite cycle life.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Semiconductor Device (Comparative Example)

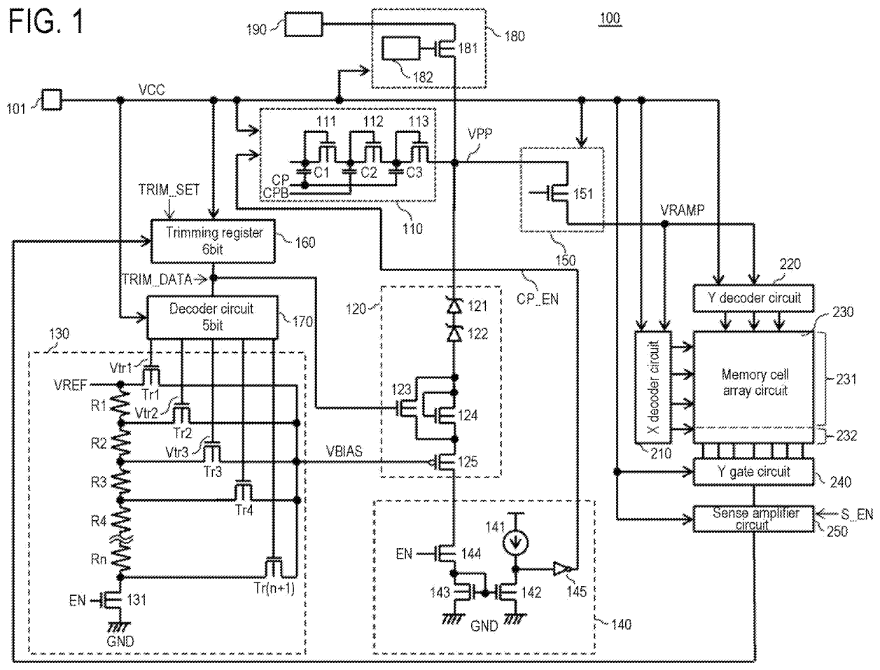

FIG. 1 is a diagram showing a comparative example of a semiconductor device (which has a general configuration to be compared with embodiments to be described later). The semiconductor device 100 of this comparative example is a semiconductor memory device (such as an electrically erasable programmable read-only memory (EEPROM) or a flash memory) in which data can be electrically re-written. The semiconductor device 100 can be widely used for storing various programs or data in, for example, consumer equipment or industrial equipment.

Referring to the figure, the semiconductor device 100 includes an X decoder circuit 210, a Y decoder circuit 220, a memory cell array circuit 230, a Y gate circuit 240, and a sense amplifier circuit 250.

The semiconductor device 100 further includes a power supply input terminal 101, a boosted voltage generation circuit 110, a voltage adjustment circuit 120, a ladder resistance circuit 130, a current mirror circuit 140, a ramp circuit 150, a trimming register 160, a decoder circuit 170, a voltage input/output circuit 180, and a test measurement pad 190.

In the memory cell array circuit 230, most parts are normally used memory cells 231 for data storage, and the rest are memory cells 232 for voltage correction. As for the circuit configuration of the memory cell array circuit 230, existing well-known technology can be applied, and therefore, detailed explanation thereof will be omitted.

The boosted voltage generation circuit 110 generates a boosted voltage VPP using a power supply voltage VCC input from the power supply input terminal 101. The power supply voltage VCC is, for example, 1.5 V to 5.0 V. The boosted voltage generation circuit 110 may be, for example, a charge pump circuit including transistors 111 to 113 and capacitors C1 to C3.

A charge pumping signal CP is applied to control electrodes of the transistors 111 and 113 via the capacitors C1 and C3, respectively. An inverted charge pumping signal CPB (which is a complementary signal of the charge pumping signal CP) is applied to a control electrode of the transistor 112 via the capacitor C2. These generate the boosted voltage VPP and a ramp voltage VRAMP that are applied to the X decoder circuit 210 and the Y decoder circuit 220. Further, the ramp voltage VRAMP (and thus the boosted voltage VPP) can be used as a write voltage for writing data into the memory cell array circuit 230.

The voltage adjustment circuit 120 is coupled, as a load, to an output end of the boosted voltage generation circuit 110. Therefore, the level of the boosted voltage VPP is uniquely determined by the voltage adjustment circuit 120. Further, the boosted voltage generation circuit 110 has the ability to output a high voltage (for example, about 30V), which is sufficiently higher than the boosted voltage VPP adjusted by the voltage adjustment circuit 120, in a no-load state.

The voltage adjustment circuit 120 includes constant voltage elements 121 and 122, transistors 123 and 124, and a voltage setting input transistor 125. A first end (cathode) of the constant voltage element 121 is connected to the output end of the boosted voltage generation circuit 110. A second end (anode) of the constant voltage element 121 is connected to a first end (cathode) of the constant voltage element 122. The other end (anode) of the constant voltage element 122 is connected in common to the drains of the transistors 123 and 124.

The constant voltage elements 121 and 122 are, for example, Zener diodes. A Zener voltage between the anode and the cathode of each of the constant voltage elements 121 and 122 is, for example, 7.5V.

The gate of the transistor 123 is connected to the trimming register 160. The source of the transistor 123 is connected to the source of the voltage setting input transistor. The diode-connected transistor 124 is connected in parallel with the transistor 123. By turn-on/off of the transistor 123, the operation of the transistor 124 is turned off/on. The magnitude of the boosted voltage VPP is adjusted by turn-on/off of the transistor 124. That is, the boosted voltage VPP can have a difference corresponding to the threshold voltage of the transistor 124 between when the transistor 124 is turned on and when the transistor 124 is turned off. The number of stages of the transistor 124 is not limited to one, and may be two or more. Further, instead of the transistor 124, a transistor, a diode, and a resistor may be arbitrarily combined to set a predetermined voltage.

From the viewpoint of power saving, the voltage setting input transistor 125 is preferably configured with a PMOS (P-channel type metal oxide semiconductor) transistor. Of course, the voltage setting input transistor 125 can also be configured with a PNP bipolar transistor. However, in that case, since a base current is generated, it is somewhat inferior in terms of power saving. Further, it is also possible to employ an NMOS (N-channel type MOS) transistor as the voltage setting input transistor 125. However, the reason that the PMOS transistor is used as the voltage setting input transistor 125 is because a circuit configuration is adopted in which voltages generated by the constant voltage elements 121 and 122 are added to the source side of the voltage setting input transistor 125 and the circuit configuration is coupled to the boosted voltage generation circuit 110.

When using Zener diodes or diodes as the constant voltage elements 121 and 122 and adding the threshold voltage of the transistor 124 to them to generate the boosted voltage VPP, it is important to consider a temperature dependence of these elements.

For example, consider a case where Zener diodes each having a Zener voltage of about 7.5 V are used as the constant voltage elements 121 and 122. In this case, the temperature dependence of the Zener voltage exhibits a positive slope (positive temperature dependence) that increases in proportion to the temperature (for example, the junction temperature Tj or the ambient temperature Ta). The temperature coefficient is, for example, 2 mV/° C.

On the other hand, the temperature dependence of each of the transistors 123 and 124 exhibits a negative slope (negative temperature dependence) that decreases in proportion to the temperature. Therefore, the negative temperature dependence of the transistors 123 and 124 acts to cancel the positive temperature dependence of the constant voltage elements 121 and 122, respectively. The magnitude of the Zener voltage is preferably set in a range of 6 V to 8 V, although it depends on the magnitude of the boosted voltage VPP.

Within this range, the temperature dependence of the Zener voltage can be set to be substantially flat, or a substantially equal absolute value that is opposite to the slope of the temperature dependence of the threshold voltage between the source and the gate of the voltage setting input transistor 125. With such a circuit configuration, the temperature dependence of the boosted voltage VPP can be kept small.

The ladder resistance circuit 130 includes a plurality of resistors R1 to Rn, a plurality of transistors Tr1 to Tr(n+1), and a resistance circuit enable transistor 131. The resistance circuit enable transistor 131 is connected in series to a resistance ladder in which the plurality of resistances R1 to Rn are connected in series. The resistance circuit enable transistor 131 is connected to a downstream side of the resistance ladder (between an application end of a ground potential GND and the resistance ladder). Of course, the resistance circuit enable transistor 131 may be connected to an upstream side of the resistance ladder (between an application end of a reference voltage VREF and the resistance ladder).

A first end of the resistor R1 is connected to the application end of the reference voltage VREF and the drain of the transistor Tr1. The reference voltage VREF is generated by, for example, a band gap constant voltage circuit. The magnitude of the reference voltage VREF is, for example, 1.2 V.

A second end of the resistor R1 and a first end of the resistor R2 are both connected to the drain of the transistor Tr2. A second end of the resistor R2 and a first end of the resistor R3 are both connected to the drain of the transistor Tr3. A second end of the resistor R3 and a first end of the resistor R4 are both connected to the drain of the transistor Tr4.

Similarly, for example, twenty to sixty resistors are connected in series, with a second end of the resistor R4 being connected to a first end of the resistor R5 (not shown). Further, a second end of the resistor Rn and the drain of the resistance circuit enable transistor 131 are both connected to the drain of the transistor Tr(n+1).

A divided voltage obtained by dividing the reference voltage VREF is generated at a connection node between adjacent resistors. The resistance values of the resistors R1 to Rn used in the ladder resistance circuit 130 are all equal. Further, if the number n of the resistors is thirty (Rn=R30), one divided voltage is 40 mV (1.2 V/30=0.04 V).

An enable signal EN for enabling the ladder resistance circuit 130 is applied to the gate of the resistance circuit enable transistor 131. The resistors R1 to Rn are made of polysilicon used for gate electrodes of MOS transistors. The size of each of the resistors R1 to Rn may be selected to be 50 kΩ to 200 kΩ for power saving.

Further, it is preferable that the divided voltage generated by the ladder resistance circuit 130 be as small as possible. If the divided voltage is in a range of 10 mV to 100 mV, it corresponds to a magnitude which is one order of magnitude smaller than the threshold voltage of a MOS transistor or the base-emitter voltage VBE of a bipolar transistor. This allows fine adjustment of the boosted voltage VPP.

As described above, for example, twenty to sixty resistors R1 to Rn are connected in series between the reference voltage VREF and the ground potential GND. The transistors Tr1 to Tr(n+1) and the resistance circuit enable transistor 131 are composed of, for example, NMOS transistors.

The sources of the transistors Tr1 to Tr(n+1) are all connected to a common connection node (which is an application end of a bias voltage VBIAS). This common connection node is connected to the gate of the voltage setting input transistor 125 forming the voltage adjustment circuit 120 in the subsequent stage.

Another feature of the ladder resistance circuit 130 is that it does not short-circuit the plurality of resistors R1 to Rn when adjusting the boosted voltage VPP. Therefore, no change occurs in a current flowing through the ladder resistance circuit 130. Further, the current does not change even when the transistors Tr1 to Tr(n+1) are turned on/off. A change in current can also cause noise, but with this configuration, such a problem can be prevented.

Assuming that the gate voltage of the voltage setting input transistor 125 is VBIAS, the source-gate threshold voltage of the voltage setting input transistor 125 is Vpth, the gate-source threshold voltage of the transistor 124 is Vnth, the constant voltage elements 121 and 122 are Zener diodes, and their Zener voltages are respectively VZ, the boosted voltage VPP is expressed by the following two equations.

The first equation is when the transistor 123 is turned on, and can be expressed as VPP1=VBIAS+Vpth+2·VZ. The second equation is when the transistor 123 is turned off, and can be expressed as VPP2=VBIAS+Vpth+Vnth2+2·VZ. Here, if VBIAS=0.6 V, Vpth=1.2 V, Vnth=1.2 V, and VZ=7.5 V, then VPP1=16.8 V and VPP2=18.0 V.

In this way, the voltage adjustment circuit 120 has a function of limiting the boosted voltage VPP to a predetermined clamp voltage VPP1 or VPP2 by using the constant voltage elements 121 and 122.

Each of the gates of the transistors Tr1 to Tr(n+1) is connected to the decoder circuit 170.

The current mirror circuit 140 is connected to the ground potential GND side of the voltage adjustment circuit 120. Referring to the figure, the current mirror circuit 140 includes a constant current source 141, transistors 142 to 144, and an inverter 145.

The transistors 142 to 144 each include a first main electrode, a second main electrode, and a control electrode, and constitute a current mirror circuit. When the transistors 142 to 144 are MOS transistors, the first main electrode and the second main electrode correspond to a drain and a source. When the first main electrode is, for example, the drain, the second main electrode is the source. Conversely, when the first main electrode is, for example, the source, the second main electrode is the drain.

The transistors 142 to 144 can also be composed of bipolar transistors. When the transistors 142 to 144 are bipolar transistors, the first main electrode and the second main electrode correspond to a collector and an emitter, and the control electrode corresponds to a base.

In this comparative example, the transistors 142 to 144 are all composed of NMOS transistors. The drain of the transistor 144 is connected to the source of the voltage setting input transistor 125. The source of the transistor 144 is connected to the drain and gate of the diode-connected transistor 143 and the gate of the transistor 142. The same enable signal EN applied to the gate of the resistance circuit enable transistor 131 is applied to the gate of the transistor 144. Therefore, the ladder resistance circuit 130 and the current mirror circuit are turned on/off in synchronization. Each of the sources of the transistors 142 and 143 is connected to the ground potential GND. The drain of the transistor 142 is connected to the constant current source 141.

An input end of the inverter 145 is connected to the drain of the transistor 142. A charge enable signal CP_EN is output from an output end of the inverter 145 (which is an output end of the current minor circuit 140) toward the boosted voltage generation circuit 110. The charge enable signal CP_EN is a signal for operating the boosted voltage generation circuit 110 in either a normal mode or a power saving mode.

For example, when the boosted voltage VPP has not reached a predetermined level, a sufficient voltage cannot be applied to the voltage adjustment circuit 120. Therefore, a sufficient current cannot be supplied to the transistors 143 and 144. At this time, the transistor 142 does not reach the turn-on state, and its ability to draw in the constant current source 141 becomes insufficient. Therefore, the drain of the transistor 142 is placed at a high level. As a result, the output (the charge enable signal CP_EN) of the inverter 145 has a low level. In such a state, the boosted voltage generation circuit 110 is controlled to be in a normal operating state.

In contrast, when the boosted voltage VPP has reached the predetermined level, a predetermined current is supplied from the constant current source 141 to the transistor 142. Therefore, the input and output of the inverter 145 are at a low level and a high level, respectively. In this state, since the boosted voltage VPP has reached the predetermined level, the boosted voltage generation circuit 110 is operated in the power saving mode.

The current mirror circuit 140 has a function of setting a current flowing through the voltage adjustment circuit 120 and the boosted voltage generation circuit 110. Further, the current mirror circuit 140 also plays a role of detecting the magnitude of the boosted voltage VPP generated by the boosted voltage generation circuit 110 and controlling the circuit operations of the voltage adjustment circuit 120 and the boosted voltage generation circuit 110.

The ramp circuit 150 is connected between the boosted voltage generation circuit 110 and the memory cell array circuit 230 and the like. The ramp circuit 150 includes, for example, a depletion transistor 151. A so-called slope voltage with a sloped voltage rise is applied to the gate of the depletion transistor 151. Thus, the ramp voltage VRAMP having a slope shape is supplied to the X decoder circuit 210 and the Y decoder circuit 220. This alleviates a stress applied to the X decoder circuit 210, the Y decoder circuit 220, and the memory cells.

The reason for employing the depletion transistor 151 is to turn on the drain-source voltage at 0 V. Thereby, the boosted voltage VPP generated in the boosted voltage generation circuit 110 can be, as it is, transmitted to the output side of the ramp circuit 150, that is, the X decoder circuit 210, the Y decoder circuit 220, etc. The ramp circuit 150 also plays a role of a buffer between the boosted voltage generation circuit 110 side and both the X decoder circuit 210 and the Y decoder circuit 220.

The trimming register 160 plays a role as a relay register when supplying a trimming voltage of the boosted voltage VPP stored in the voltage correction memory cell 232 to the ladder resistance circuit 130. The trimming register 160 is composed of, for example, 6 bits.

The trimming register 160 stores a trimming value (TRIM_DATA) taken out from the voltage correction memory cell 232. The voltage correction memory cell 232 stores the trimming value (TRIM_DATA) from 0 V to 1.2 V in a step of 40 mV, for example.

For example, assume that a set target value of the boosted voltage VPP is set to 16.88 V. Here, when the bias voltage VBIAS is set to 0.6 V, which is ½ of the reference voltage VREF (1.2 V), assume that the boosted voltage VPP measured by the test measurement pad 190 is 16.84 V. In this case, the boosted voltage VPP is lower by 0.04 V (40 mV) than the set target value. Therefore, the trimming value (TRIM_DATA) of 0.04 V (40 mV) stored in the voltage correction memory cell 232 is stored in the trimming register 160 via the sense amplifier circuit 250 and the like.

The trimming value (TRIM_DATA) stored in the trimming register 160 is input to the decoder circuit 170. The decoder circuit 170 converts the trimming value (TRIM_DATA) into a control signal of the ladder resistance circuit 130. That is, the decoder circuit 170 includes a decoder for decoding encoded data stored in the trimming register 160. The decoder is composed of, for example, 5 bits.

The control signal decoded by the decoder circuit 170 drives the ladder resistance circuit 130 in a subsequent stage. Referring to the figure, the control signals of the ladder resistance circuit 130 are gate signals VTr1 to VTr(n+1) of the transistors Tr1 to Tr(n+1), respectively.

In the ladder resistance circuit 130, one of the transistors Tr1 to Tr(n+1) is selectively turned on to output the bias voltage VBIAS of 0.64 V (0.6 V+0.04 V). Further, the bias voltage VBIAS and the boosted voltage VPP are set when the semiconductor device 100 is in a wafer state.

The voltage input/output circuit 180 is used as an output switch when outputting the adjusted boosted voltage VPP to the test measurement pad 190. Further, the voltage input/output circuit 180 is used as an input switch that applies a stress voltage during a stress test on the memory cell array circuit 230 side.

The test measurement pad 190 is used as a measurement terminal when the semiconductor device 100 is in a wafer state. The test measurement pad 190 is also used as a stress voltage application terminal.

The voltage input/output circuit 180 includes a transistor 181 and a switch voltage applying means 182. A voltage having two levels, a high level and a low level, for turning on or off the transistor 181 is applied to the switch voltage applying means 182 in a switched manner.

When the boosted voltage VPP is not output to the test measurement pad 190 and when the stress voltage is not applied to the memory cell array circuit 230 and the like, the gate of the transistor 181 is fixed at a low level or a high level. When an NMOS transistor is used as the transistor 181, the gate of the transistor 181 is fixed at a low level. On the other hand, when a PMOS transistor is used as the transistor 181, the gate of the transistor 181 is fixed at a high level.

In the semiconductor device 100 of this comparative example, the boosted voltage VPP can be finely adjusted in units of several tens of mV by the ladder resistance circuit 130. Therefore, it is possible to regulate the boosted voltage VPP with high precision without depending on manufacturing variations in the Zener diodes or diodes used as the constant voltage elements 121 and 122.

### Considerations Regarding Comparative Example

However, in the semiconductor device 100 of this comparative example, the Zener voltages in the constant voltage elements 121 and 122 of the voltage adjustment circuit 120 have a positive temperature dependence. As described above, when the transistors 123 and 124 have a negative temperature dependence, their temperature dependencies cancel each other out, so that the temperature dependence of the boosted voltage VPP can be kept small. However, it is by no means easy to make the temperature dependence of the boosted voltage VPP close to be flat. Further, a configuration in which the voltage adjustment circuit 120 does not include the transistors 123 and 124 is also conceivable.

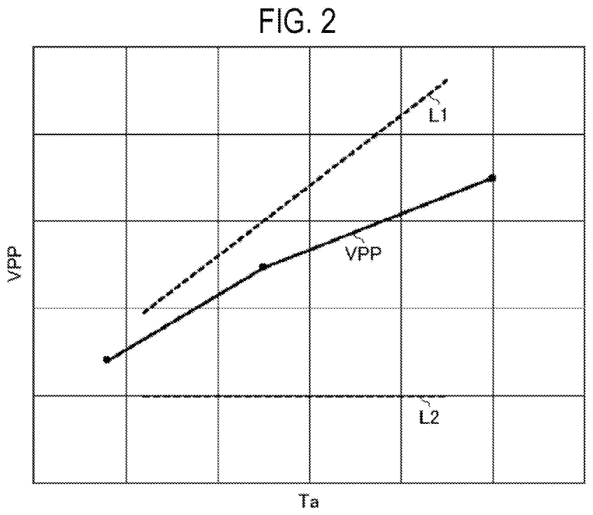

FIG. 2 is a diagram showing a temperature dependence (in this figure, the dependence on the ambient temperature Ta) of the boosted voltage VPP in the comparative example (FIG. 1). A solid line in the figure indicates the boosted voltage VPP. On the other hand, a broken line L1 indicates a breakdown voltage line of a high breakdown voltage element integrated into the semiconductor device 100. Further, a broken line L2 indicates a lower limit value of the boosted voltage VPP necessary for data write in the memory cell array circuit 230.

As shown in this figure, the boosted voltage VPP increases as the ambient temperature Ta rises. In other words, the boosted voltage VPP has a positive temperature dependence. This is because the positive temperature dependence of the constant voltage elements 121 and 122 (for example, Zener diodes) is not canceled.

When the boosted voltage VPP has a positive temperature dependence, the boosted voltage VPP deviates from the broken line L2 and rises to a value near the broken line L1 at a high temperature. If an excessive boosted voltage VPP is applied to the memory cell array circuit 230 in this way, there is a possibility that the rewrite cycle life of the memory cell array circuit 230 will be shortened. Further, there is a concern that the device may be destroyed due to the application of a high voltage, resulting in low reliability.

In the following, in view of the above considerations, novel embodiments, which can realize appropriate adjustment of the boosted voltage VPP (for example, further flattening or arbitrary slope adjustment of temperature dependence), are suggested.

### Semiconductor Device (First Embodiment)

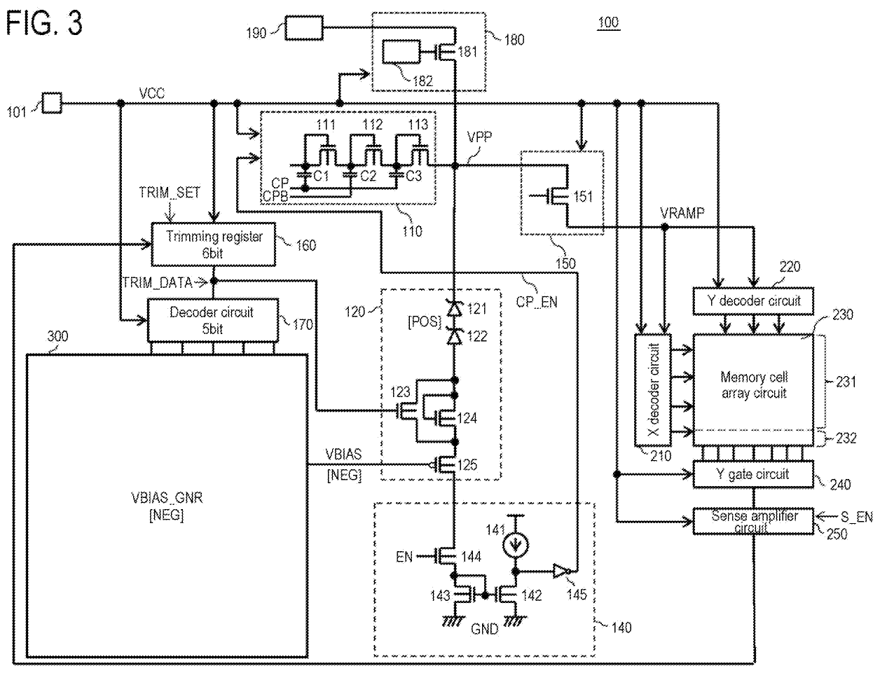

FIG. 3 is a diagram showing a first embodiment of a semiconductor device 100. The semiconductor device 100 of this embodiment is based on the previously-described comparative example (FIG. 1), but includes a bias voltage generation circuit 300 in place of the ladder resistance circuit 130.

The bias voltage generation circuit 300 generates a bias voltage VBIAS with a negative temperature dependence (denoted as [NEG] in the figure). That is, the bias voltage VBIAS has a negative temperature gradient such that a voltage value decreases as the ambient temperature Ta increases. In other words, the negative temperature dependence of the bias voltage VBIAS and the positive temperature dependence (denoted as [POS] in this diagram) of the Zener voltages of the constant voltage elements 121 and 122 have opposite polarities (positive and negative).

The bias voltage generation circuit 300 adjusts the upper limit value (which is the aforementioned clamp voltage VPP1 or VPP2) of the boosted voltage VPP by applying the bias voltage VBIAS to the gate of the voltage setting input transistor 125 of the voltage adjustment circuit 120. In this respect, there is no particular difference from the previously-described comparative example (FIG. 1).

Thus, by applying the bias voltage VBIAS having the negative temperature dependence [NEG] to the voltage adjustment circuit 120, the positive temperature dependence [POS] of each of the constant voltage elements 121 and 122 is canceled. Therefore, the temperature dependence of the boosted voltage VPP can be approximated to be flat. As a result, for example, the excessive boosted voltage VPP can be prevented from being output at a high temperature.

Further, in the semiconductor device 100 of this embodiment, the temperature dependence of the boosted voltage VPP can be arbitrarily adjusted by adjusting the negative temperature dependence [NEG] of the bias voltage VBIAS. Therefore, for example, by controlling the negative temperature dependence [NEG] of the bias voltage VBIAS from outside the semiconductor device 100, it is possible to flexibly adjust the boosted voltage VPP to conform with the application and specifications (memory cell characteristics, element breakdown voltage, etc.) of the semiconductor device 100.

In this embodiment, an example is given in which the constant voltage elements 121 and 122 have a positive temperature dependence [POS] and the bias voltage VBIAS has a negative temperature dependence [NEG]. However, the relationship between the two is not limited to the above. That is, it is sufficient that the constant voltage elements 121 and 122 have a first temperature dependence and the bias voltage VBIAS has a second temperature dependence, the polarity of which is opposite to the first temperature dependence.

### Semiconductor Device (Second Embodiment)

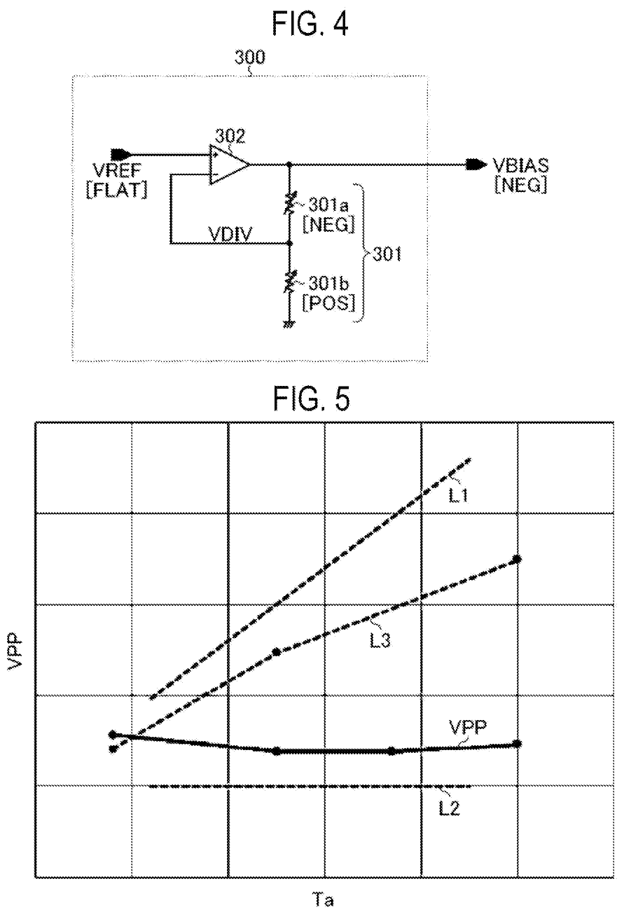

FIG. 4 is a diagram showing a second embodiment of the semiconductor device 100. The semiconductor device 100 of this embodiment is based on the previously-described first embodiment (FIG. 3), but clearly shows an example of the internal configuration of the bias voltage generation circuit 300. Referring to this figure, the bias voltage generation circuit 300 of this embodiment includes a feedback resistance part 301 and an amplifier 302.

The feedback resistance part 301 generates a divided voltage VDIV according to the bias voltage VBIAS. Referring to this figure, the feedback resistance part 301 includes resistors 301a and 301b. The resistor 301a is connected between an application end of the bias voltage VBIAS (which is an output end of the amplifier 302) and an application end of the divided voltage VDIV. The resistor 301b is connected between the application end of the divided voltage VDIV and a ground end.

The resistor 301a may be a resistive element with a negative temperature dependence [NEG]. The resistor 301a may be, for example, a poly resistor. The poly resistor is a resistive element that utilizes a resistance component of a polysilicon layer.

The resistor 301b may be a resistive element with a positive temperature dependence [POS]. The resistor 301b may be, for example, an N-type well resistor or a tunnel resistor. The N-type well resistor is a resistive element that utilizes a resistance component of an N-type well. Further, the tunnel resistor is a resistive element that utilizes a resistance component of a tunnel region having a polysilicon layer formed on its surface.

However, the temperature dependence of each of the resistors 301a and 301b can be arbitrarily adjusted within a range where the bias voltage VBIAS has the negative temperature dependence [NEG].

Further, at least one of the resistance values of the resistors 301a and 301b may be arbitrarily adjustable by trimming or the like.

The amplifier 302 controls the bias voltage VBIAS output from the output end so that the previous divided voltage VDIV input to the inverting input terminal (—) and a predetermined reference voltage VREF input to the non-inverting input terminal (+) are imaginary short-circuited. Note that the temperature dependence of the reference voltage VREF may be flat. The reference voltage VREF may be generated by, for example, a depletion type voltage source.

FIG. 5 is a diagram showing a temperature dependence (in this figure, the dependence on the ambient temperature Ta) of the boosted voltage VPP in the second embodiment (FIG. 4). A solid line in the figure indicates the boosted voltage VPP. On the other hand, a broken line L1 indicates a breakdown voltage line of a high breakdown voltage element integrated into the semiconductor device 100. Further, a broken line L2 indicates a lower limit value of the boosted voltage VPP necessary for data write in the memory cell array circuit 230. Further, a broken line L3 indicates the temperature dependence of the boosted voltage VPP in the comparative example (FIG. 1) for comparison.

As shown in this figure, the temperature dependence of the boosted voltage VPP (indicated by the solid line) in this embodiment is almost flat, unlike the comparative example (indicated by the broken line L3). Therefore, an increase in the boosted voltage VPP at a high temperature is suppressed. As a result, the rewrite cycle life of the memory cell array circuit 230 becomes longer. Further, reliability is improved because concerns about element destruction due to the application of a high voltage are eliminated.

### Semiconductor Device (Third Embodiment)

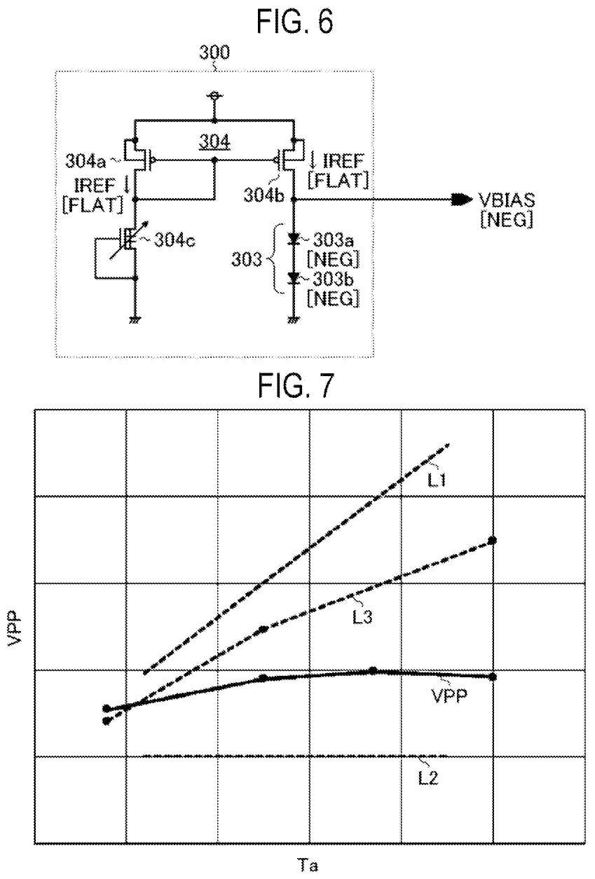

FIG. 6 is a diagram showing a third embodiment of the semiconductor device 100. The semiconductor device 100 of this embodiment is based on the previously-described first embodiment (FIG. 3), but clearly shows an example of the internal configuration of the bias voltage generation circuit 300. Referring to the figure, the bias voltage generation circuit 300 of this embodiment includes a diode string 303 and a reference current generation part 304.

The diode string 303 includes multiple stages (two stages in this figure) of diodes 303a and 303b. The anode of the diode 303a is connected to an application end of the bias voltage VBIAS. The cathode of the diode 303a is connected to the anode of the diode 303b. The cathode of the diode 303b is connected to a ground end.

The forward effect voltages Vf of the diodes 303a and 303b both have a negative temperature dependence [NEG]. Therefore, the bias voltage VBIAS (=2×Vf) drawn from the anode of the diode string 303 also has a negative temperature dependence [NEG].

The reference current generation part 304 generates a predetermined reference current IREF flowing through the diode string 303. Referring to the figure, the reference current generation part 304 includes transistors 304a and 304b (for example, PMOSFETs) and a transistor 304c (for example, a depletion type NMOSFET).

The sources of the transistors 304a and 304b are both connected to a power supply end. The gates of the transistors 304a and 304b are both connected to the drain of the transistor 304a. The drain of the transistor 304a is connected to the drain of the transistor 304c. The drain of the transistor 304b is connected to the application end of the bias voltage VBIAS. The gate and source of the transistor 304c are both connected to a ground end.

The transistor 304c functions as a current source that generates a predetermined reference current IREF. The temperature dependence of the reference current IREF may be flat. Further, the reference current IREF of the transistor 304c may be arbitrarily adjustable by trimming or the like.

The transistors 304a and 304b function as a current mirror that mirrors the reference current IREF input to the drain of the transistor 304a and outputs it from the drain of the transistor 304b.

FIG. 7 is a diagram showing a temperature dependence (in this figure, the dependence on the ambient temperature Ta) of the boosted voltage VPP in the third embodiment (FIG. 6). A solid line in the figure indicates the boosted voltage VPP. On the other hand, a broken line L1 indicates a breakdown voltage line of a high breakdown voltage element integrated into the semiconductor device 100. Further, a broken line L2 indicates a lower limit value of the boosted voltage VPP necessary for data write in the memory cell array circuit 230. Further, a broken line L3 indicates the temperature dependence of the boosted voltage VPP in the comparative example (FIG. 1) for comparison.

As shown in this figure, the temperature dependence of the boosted voltage VPP (indicated by the solid line) in this embodiment is almost flat, unlike the comparative example (indicated by the broken line L3). Therefore, an increase in the boosted voltage VPP at a high temperature is suppressed. As a result, the rewrite cycle life of the memory cell array circuit 230 becomes longer. Further, reliability is improved because concerns about element destruction due to the application of a high voltage are eliminated. That is, in this embodiment, the same effects as in the previously-described second embodiment (FIG. 4) can be obtained.

### Semiconductor Device (Fourth Embodiment)

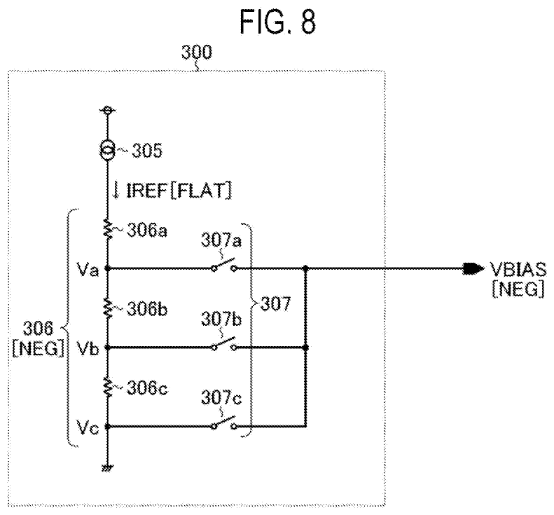

FIG. 8 is a diagram showing a fourth embodiment of the semiconductor device 100. The semiconductor device 100 of this embodiment is based on the previously-described first embodiment (FIG. 3), but clearly shows an example of the internal configuration of the bias voltage generation circuit 300. Referring to this figure, the bias voltage generation circuit 300 of this embodiment includes a current source 305, a resistance ladder part 306, and a voltage selection part 307.

The current source 305 generates a predetermined reference current IREF. The temperature dependence of the reference current IREF may be flat. Further, the reference current IREF may have a negative temperature dependence [NEG].

The resistance ladder part 306 is connected in series between the current source 305 and the ground end and generates a plurality of node voltages (node voltages Va, Vb, and Vc in the figure) having a negative temperature dependence [NEG]. Referring to this figure, the resistance ladder part 306 includes resistors 306a, 306b, and 306c. The resistor 306a is connected between the current source 305 and an application end of the node voltage Va. The resistor 306b is connected between the application end of the node voltage Va and an application end of the node voltage Vb. The resistor 306c is connected between the application end of the node voltage Vb and an application end of the node voltage Vc (which is the ground end). The resistors 306a, 306b, and 306c may each be a resistive element (for example, a poly resistor) having a negative temperature dependence [NEG].

The voltage selection part 307 outputs one of the node voltages Va, Vb, and Vc, as the bias voltage VBIAS. Referring to this figure, the voltage selection part 307 includes switches 307a, 307b, and 307c. A first end of the switch 307a is connected to the application end of the node voltage Va. A first end of the switch 307b is connected to the application end of the node voltage Vb. A first end of the switch 307c is connected to the application end of the node voltage Vc (which is the ground end). Second ends of the switches 307a, 307b, and 307c are all connected to an application end of the bias voltage VBIAS. The switches 307a, 307b, and 307c are selectively turned on, for example, in response to a control signal from the decoder circuit 170.

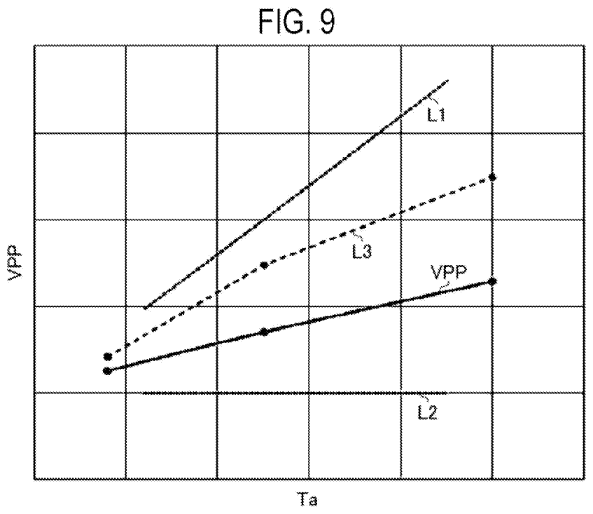

FIG. 9 is a diagram showing a temperature dependence (in this figure, the dependence on the ambient temperature Ta) of the boosted voltage VPP in the fourth embodiment (FIG. 8). A solid line in the figure indicates the boosted voltage VPP. On the other hand, a broken line L1 indicates a breakdown voltage line of a high breakdown voltage element integrated into the semiconductor device 100. Further, a broken line L2 indicates a lower limit value of the boosted voltage VPP necessary for data write in the memory cell array circuit 230. Further, a broken line L3 indicates the temperature dependence of the boosted voltage VPP in the comparative example (FIG. 1) for comparison.

As shown in this figure, the temperature dependence of the boosted voltage VPP (indicated by the solid line) in this embodiment has a smaller slope than in the comparative example (indicated by the broken line L3). That is, unlike the previously-described second embodiment (FIG. 5) and third embodiment (FIG. 7), the boosted voltage VPP (indicated by the solid line) in this embodiment changes with a certain slope with respect to the ambient temperature Ta. Therefore, it is possible to flexibly adjust the boosted voltage VPP to conform with the application and specifications (memory cell characteristics, element breakdown voltage, etc.) of the semiconductor device 100.

### Semiconductor Device (Fifth Embodiment)

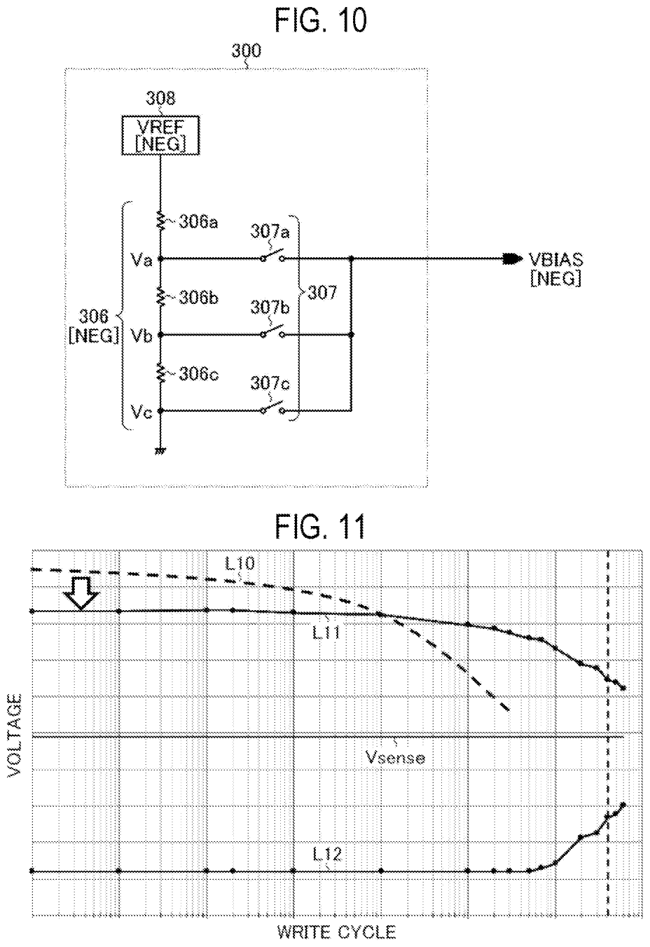

FIG. 10 is a diagram showing a fifth embodiment of the semiconductor device 100. The semiconductor device 100 of this embodiment is based on the previously-described fourth embodiment (FIG. 8), but the internal configuration of the bias voltage generation circuit 300 is modified. Referring to this figure, the bias voltage generation circuit 300 of this embodiment includes a reference voltage generation part 308 in place of the previously-described current source 305.

The reference voltage generation part 308 generates a reference voltage VREF having a negative temperature dependence [NEG] and supplies it to the resistance ladder part 306.

This embodiment provides the same operation and effects as the previously-described fourth embodiment (FIG. 8).

<Rewrite Cycle Life>

FIG. 11 is a diagram showing improved effects of the rewrite cycle life in the first to fifth embodiments. The horizontal axis in this figure represents rewrite cycle (the number of data rewrites) of the memory cell array circuit 230. The vertical axis in this figure indicates voltage values of a bit signal L11 and an inverted bit signal L12 read from the memory cell array circuit 230, and a read sense voltage Vsense. Further, a broken line L10 in the figure indicates a bit signal in the comparative example (FIG. 1) for comparison.

As shown in this figure, deterioration of the memory cell array circuit 230 is suppressed by lowering (suppressing an increase in) the boosted voltage VPP at a high temperature. Therefore, it is expected that the rewrite cycle life will be improved and further a guaranteed number of rewrites will be increased.

In this way, the techniques suggested in the first to fifth embodiments are suitable for the semiconductor device 100 (so-called memory IC) including the memory cell array circuit 230. Further, these techniques can be widely applied to all semiconductor devices that have a function of generating a boosted voltage (high voltage) inside the device.

<Supplementary Notes>

Below, the above-described various embodiments will be comprehensively described.

A semiconductor device disclosed in the present disclosure includes a configuration (first configuration) which includes: a boosted voltage generation circuit configured to generate a boosted voltage; a voltage adjustment circuit configured to limit the boosted voltage to a predetermined clamp voltage or lower by using a constant voltage element having a first temperature dependence; and a bias voltage generation circuit configured to adjust the clamp voltage by using a bias voltage having a second temperature dependence that is opposite in polarity to the first temperature dependence.

The semiconductor device of the first configuration may include a configuration (second configuration) that the voltage adjustment circuit includes a transistor connected in series with the constant voltage element and including a control end to which the bias voltage is applied.

The semiconductor device of the first or second configuration may include a configuration (third configuration) that the bias voltage generation circuit includes a feedback resistance part configured to generate a divided voltage according to the bias voltage, and an amplifier configured to receive input of the divided voltage and a predetermined reference voltage to control the bias voltage, the feedback resistance part includes a first resistor connected between an application end of the bias voltage and an application end of the divided voltage, and a second resistor connected between the application end of the divided voltage and a ground end, and the first resistor has the second temperature dependence, or the second resistor has the first temperature dependence, or the first resistor has the second temperature dependence and the second resistor has the first temperature dependence.

The semiconductor device of the third configuration may include a configuration (fourth configuration) that the feedback resistance part is configured such that at least one of resistance values of the first resistor and the second resistor is adjustable.

The semiconductor device of the first or second configuration may include a configuration (fifth configuration) that the bias voltage generation circuit includes at least one stage of diode string configured to output a forward drop voltage having the second temperature dependence as the bias voltage.

The semiconductor device of the fifth configuration may include a configuration (sixth configuration) that the bias voltage generation circuit further includes a reference current generation part configured to generate a predetermined reference current flowing through the diode string.

The semiconductor device of the sixth configuration may include a configuration (seventh configuration) that the reference current generation part is configured such that the reference current is adjustable.

The semiconductor device of the first or second configuration may include a configuration (eighth configuration) that the bias voltage generation circuit includes a current source configured to generate a predetermined reference current, a resistance ladder part connected in series between the current source and a ground end and configured to generate a plurality of node voltages having the second temperature dependence, and a voltage selection part configured to output one of the plurality of node voltages as the bias voltage.

The semiconductor device of the first or second configuration may include a configuration (ninth configuration) that the bias voltage generation circuit includes a reference voltage generation part configured to generate a reference voltage having the second temperature dependence, a resistance ladder part connected in series between the reference voltage generation part and a ground end and configured to generate a plurality of node voltages, and a voltage selection part configured to output one of the plurality of node voltages as the bias voltage.

The semiconductor device of any one of the first to ninth configurations may include a configuration (tenth configuration) that further includes: a memory cell array circuit configured such that data are written by using the boosted voltage.

<Others>

The various technical features disclosed in the present disclosure can be modified in addition to the above-described embodiments without departing from the spirit of the technical creation. That is, the above-described embodiments should be considered to be illustrative in all respects and not restrictive. Further, the technical scope of the present disclosure is defined by the claims, and it should be understood that all changes within the meaning and range equivalent to the claims are included in the technical scope of the present disclosure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a boosted voltage generation circuit configured to generate a boosted voltage;
a voltage adjustment circuit configured to limit the boosted voltage to a predetermined clamp voltage or lower by using a constant voltage element having a first temperature dependence; and
a bias voltage generation circuit configured to adjust the clamp voltage by using a bias voltage having a second temperature dependence that is opposite in polarity to the first temperature dependence.

2. The semiconductor device of claim 1, wherein the voltage adjustment circuit includes a transistor connected in series with the constant voltage element and including a control end to which the bias voltage is applied.

3. The semiconductor device of claim 1, wherein the bias voltage generation circuit includes a feedback resistance part configured to generate a divided voltage according to the bias voltage, and an amplifier configured to receive input of the divided voltage and a predetermined reference voltage to control the bias voltage,
wherein the feedback resistance part includes a first resistor connected between an application end of the bias voltage and an application end of the divided voltage, and a second resistor connected between the application end of the divided voltage and a ground end, and
wherein the first resistor has the second temperature dependence, or the second resistor has the first temperature dependence, or the first resistor has the second temperature dependence and the second resistor has the first temperature dependence.

4. The semiconductor device of claim 3, wherein the feedback resistance part is configured such that at least one of resistance values of the first resistor and the second resistor is adjustable.

5. The semiconductor device of claim 1, wherein the bias voltage generation circuit includes at least one stage of diode string configured to output a forward drop voltage having the second temperature dependence as the bias voltage.

6. The semiconductor device of claim 5, wherein the bias voltage generation circuit further includes a reference current generation part configured to generate a predetermined reference current flowing through the diode string.

7. The semiconductor device of claim 6, wherein the reference current generation part is configured such that the reference current is adjustable.

8. The semiconductor device of claim 1, wherein the bias voltage generation circuit includes a current source configured to generate a predetermined reference current, a resistance ladder part connected in series between the current source and a ground end and configured to generate a plurality of node voltages having the second temperature dependence, and a voltage selection part configured to output one of the plurality of node voltages as the bias voltage.

9. The semiconductor device of claim 1, wherein the bias voltage generation circuit includes a reference voltage generation part configured to generate a reference voltage having the second temperature dependence, a resistance ladder part connected in series between the reference voltage generation part and a ground end and configured to generate a plurality of node voltages, and a voltage selection part configured to output one of the plurality of node voltages as the bias voltage.

10. The semiconductor device of claim 1, further comprising: a memory cell array circuit configured such that data are written by using the boosted voltage.
